(19) United States
(12) Patent Application Publication
(10) Pub. No.: US 2025/0309901 A1
(43) Pub. Date: Oct. 2, 2025

(54) CIRCUIT AND METHOD FOR GENERATING A CLOCK SIGNAL

(71) Applicant: STMicroelectronics International N.V., Geneva (CH)

(72) Inventors: Olivier FERRAND, Carry le Rouet (FR); Christophe EVA, Rousset (FR)

(73) Assignee: STMicroelectronics International N.V., Geneva (CH)

(21) Appl. No.: 19/084,065

(22) Filed: Mar. 19, 2025

(30) Foreign Application Priority Data
Mar. 29, 2024 (FR) FR2403229

(51) Int. Cl. H03K 21/08; H03L 7/08

(52) U.S. Cl. CPC H03K 21/08; H03L 7/08

(57) ABSTRACT

An electronic device includes a first electronic circuit that generates a first clock signal and a second signal indicating a state of stability of a frequency of the first clock signal. The second signal has a first value during a first period and a second value after the first period. A second electronic circuit of the electronic device generates an output clock signal having a frequency equal to the frequency of the first clock signal divided by a first factor when the second signal is at the first value. Alternatively, the second electronic circuit generates the output clock signal having the frequency of the first clock signal, or a frequency equal to the frequency of the first clock signal divided by a second factor smaller than the first factor, when the second signal changes to the second value.

### PRIORITY CLAIM

This application claims the priority benefit of French Application for Patent No. FR2403229 filed on Mar. 29, 2024, the content of which is hereby incorporated by reference in its entirety to the maximum extent allowable by law.

### TECHNICAL FILED

The present disclosure generally concerns the generation of clock signals in electronic circuits.

### BACKGROUND

In an electronic circuit, a clock signal is a periodic signal used to rate the operations of the circuit. The frequency of the clock signal is an important parameter to ensure the correct execution of these operations.

During the initialization of a clock signal generator of an electronic circuit, for example at the starting of the electronic circuit, the frequency of the clock signal may fluctuate around a target frequency before stabilizing.

Fluctuations of the frequency of the clock signal beyond the target frequency may cause errors in certain electronic circuits. A solution to this concern is to wait for the frequency to have stabilized before performing operations. This solution, however, causes a waste of time during the starting of electronic circuits, during which these circuits are on standby.

### SUMMARY

An embodiment provides an electronic device, comprising: a first electronic circuit configured to generate a first clock signal and generate a second signal indicating a state of stability of the frequency of the first clock signal, the second signal having a first value during a first period from the starting of the first electronic circuit and a second value after the first period; and a second electronic circuit configured to generate an output clock signal having a frequency equal to the frequency of the first clock signal divided by a first factor when the second signal is at the first value and having the frequency of the first clock signal, or a frequency equal to the frequency of the first signal divided by a second factor smaller than the first factor, as a consequence of a change of the second signal to the second value.

According to an embodiment, the first electronic circuit comprises a phase-locked loop configured to generate the first clock signal and the second signal.

According to an embodiment, the second electronic circuit comprises a frequency divider configured to perform the division of the frequency of the first clock signal.

According to an embodiment, the second electronic circuit comprises a multiplexer having an output coupled to the frequency divider, a first input configured to receive the first factor, and a second input configured to receive the second factor, the multiplexer being configured to transmit the first factor when the second signal is at the first value and to transmit the second factor when the second signal is at the second value.

According to an embodiment, the second electronic circuit comprises: a first frequency divider having an input configured to receive the first factor and configured to perform the division of the frequency of the first clock signal by the first factor; and a second frequency divider having an input configured to receive the second factor and configured to perform the division of the frequency of the first clock signal by the second factor.

According to an embodiment, the second electronic circuit comprises a multiplexer having a first input coupled to the output of the first frequency divider and a second input coupled to the output of the second frequency divider, the multiplexer being configured to transmit a signal received on the first input when the second signal is at the first value and to transmit a signal received on the second input when the second signal is at the second value.

According to an embodiment, the second circuit comprises a synchronization circuit configured to synchronize the second signal with the first clock signal.

According to an embodiment, the first factor is an integer greater than or equal to two.

Another embodiment provides a method of generating an output clock signal, comprising: generating, by a first electronic circuit, a first clock signal and a second signal indicating a state of stability of a frequency of the first clock signal, the second signal having a first value during a first period from the starting of the first electronic circuit and a second value after the first period; and generating, by a second electronic circuit, the output clock signal having a frequency equal to the frequency of the first clock signal divided by a first factor when the second signal is at the first value and having the frequency of the first clock signal, or a frequency equal to the frequency of the first clock signal divided by a second factor smaller than the first factor, as a consequence of a change of the second signal to the second value.

According to an embodiment, the method further comprises synchronizing the second signal with the first clock signal using a synchronization circuit.

According to an embodiment, the first factor is an integer greater than or equal to two.

According to an embodiment, the method further comprises, after generating the first clock signal and second signal, converting the first clock signal and second signal from analog signal into digital signals.

According to an embodiment, the method further comprises transmitting, by the second electronic circuit, via a multiplexer to a frequency divider, the first factor when the second signal is at the first value and the second factor when the second signal is at the second value.

According to an embodiment, the method further comprises dividing a frequency of the first clock signal by the first factor by a first frequency divider of the second electronic circuit and dividing the frequency of the first clock signal by the second factor by a second frequency divider of the second electronic circuit.

According to an embodiment, the method further comprises transmitting, by a multiplexer of the second electronic circuit, a signal originating from the first frequency divider when the second signal is at the first value and a signal originating from the second frequency divider when the second signal is at the second value.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A shows, in the form of blocks, an example of an electronic device generating a clock signal;

FIG. 1B shows, in the form of blocks, another example of an electronic device generating a clock signal;

FIG. 1C schematically shows in the form of blocks an example of a phase-locked loop of a circuit of FIGS. 1A and 1B;

FIG. 2 graphically shows an example of the variation of the frequency of the clock signal generated by the device of FIG. 1A or of FIG. 1B; and

FIG. 3 is a timing diagram showing an example of the signals present in the device of FIG. 1B; and

FIG. 4 shows, in the form of a flowchart, a method of generating the clock signal of FIGS. 1A to 3.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, techniques for estimating when a clock signal has become stable in frequency are known to those skilled in the art and are not detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

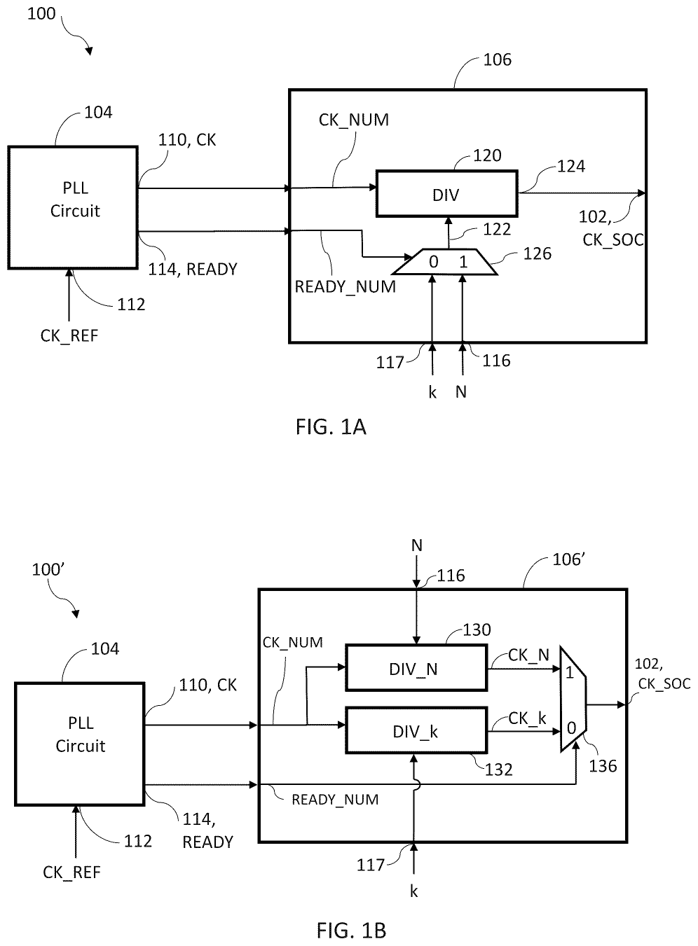

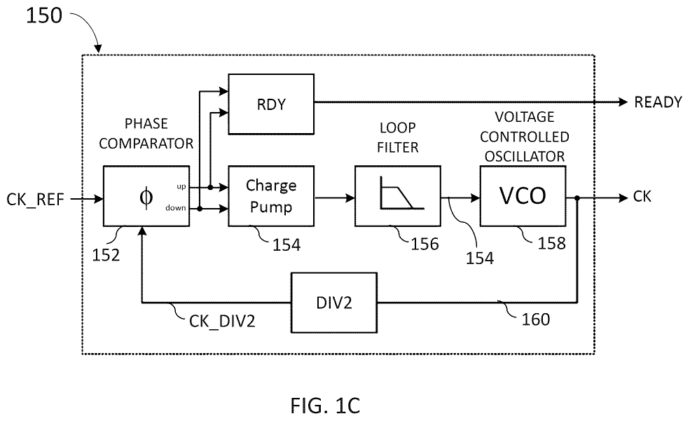

FIG. 1A shows, in the form of blocks, an example of an electronic device 100 generating an output clock signal CK_SOC at an output 102.

Electronic device 100 comprises a first circuit 104, for example an analog circuit, and a second circuit 106, for example a digital circuit. The second circuit 106 is configured to generate the output clock signal CK_SOC, which is for example supplied to a system on chip (SoC, not shown in FIG. 1A), for example comprising an assembly of digital circuits clocked by the output clock signal CK_SOC.

The first circuit 104 comprises outputs 110 and 114, and is configured to transmit to output 110 a clock signal CK and to output 114 a signal READY indicating the state of stability of signal CK.

The first circuit 104 comprises, for example, an input 112 configured to receive a reference physical parameter, for example a voltage, a current, a temperature, a frequency, etc. In the example of FIG. 1A, the reference physical parameter is a clock signal CK_REF having a reference frequency. The first circuit 104 is, for example, configured to generate clock signal CK from the reference physical parameter, for example via a phase-locked loop (PLL).

During a time interval, for example following the starting of circuit 104, clock signal CK is generated with a frequency varying over time before stabilizing around a target frequency FQ_TARGET which is a function of the reference physical parameter. Target frequency FQ_TARGET is, for example, a parameter set on design of circuit 104. Signal READY is, for example, initialized to a first value, for example, to a first voltage value, at the starting of the first circuit 104. Signal READY is configured to take a second value, for example a second voltage value, when the frequency of signal CK has become stable around FQ_TARGET. The generation of signal READY is, for example, obtained by a frequency comparator configured to compare the frequency of signal CK with frequency FQ_TARGET. For example, signal READY indicates when the amplitude of the frequency fluctuations of signal CK is smaller than x % of frequency FQ_TARGET, where x is for example in the range from 1 to 10%, and preferably equal to approximately 5%.

According to another embodiment, circuit 104 is configured to generate signal READY with the first value during a first fixed time interval from the starting of the first circuit 104 and with the second value at the end of the first time interval.

The second circuit 106 comprises inputs coupled to the output 110 and to the output 114 of circuit 104 and is configured to take as an input the clock signal CK supplied by output 110 and the signal READY supplied by output 114. The second circuit 106 also comprises inputs 116 and 117, and is configured to receive at input 116 a division factor N and at input 117 a parameter k. Division factor N and parameter k are supplied, for example, by a management system, such as a host processor (not shown). Circuit 106 is configured to generate clock signal CK_SOC. Parameter k is, for example, an integer, greater than or equal to two, corresponding to a minimum division factor to be applied to the frequency of clock signal CK to obtain a clock signal with a lower frequency, lower than FQ_TARGET, when signal READY is at the first value, for example after the starting of the first circuit 104. Division factor N is, for example, an integer smaller than or equal to k, which may vary during the use of device 100. Division factor N corresponds to the factor to be applied to the frequency of clock signal CK to obtain a clock signal with a lower frequency, for example adapted to the operation of the system on chip clocked by clock signal CK_SOC.

The signal READY generated by circuit 104 is, for example, asynchronous with signal CK. Circuit 106 comprises, for example, a synchronization circuit, not illustrated in FIG. 1A, to synchronize signal READY with signal CK and thus to obtain a synchronized digital READY_NUM signal. In certain cases, the synchronization circuit also transforms clock signal CK into a digital clock signal CK_NUM. For example, the synchronization circuit is configured to convert the voltage level present on the output 110 of circuit 104 into a compliant voltage level for digital circuits which will receive clock signal CK_NUM. Synchronization circuits are known to those skilled in the art, and the implementation of the synchronization circuit will not be described in detail.

According to an embodiment, circuit 106 comprises a frequency divider 120 (“DIV”) taking as an input signal CK_NUM and a control signal 122 and being configured to generate at an output 124 output clock signal CK_SOC.

Circuit 106 comprises, for example, a control circuit 126, for example a multiplexer. Control circuit 126 takes as inputs, for example, parameter k and division factor N and is controlled by the signal READY_NUM received at a selection input. Control circuit 126 is, for example, configured to generate control signal 122. Control signal 122 corresponds, for example, to parameter k or to division factor N, according to the value of selection signal READY_NUM.

According to an embodiment, it is desired for the output clock signal CK_SOC to be generated at a frequency equal to frequency FQ_TARGET divided by N. When signal READY_NUM is at the first value, the frequency is divided by parameter k to decrease the risk of an exceeding of frequency FQ_TARGET. Control circuit 126 is then configured so that control signal 122 indicates a division factor equal to parameter k. Frequency divider 120 is then configured to generate signal CK_SOC with a frequency equal to the frequency of signal CK_NUM divided by k. When signal READY_NUM is at the second value, control circuit 126 is then configured so that control signal 122 indicates a division factor equal to parameter N. Frequency divider 120 is then configured to generate signal CK_SOC with a frequency equal to the frequency of signal CK_NUM divided by N.

According to another embodiment, division factor N also takes values greater than k. The frequency of signal CK_NUM is then divided by N, for example, for any value of signal READY.

According to an embodiment, the value of N is equal to 1, and divider 120 does not perform a division but propagates signal CK_NUM directly to output 102. In this case, circuit 106 may also comprise a second control circuit, for example a multiplexer, not shown in FIG. 1A, configured to receive the output signal of frequency divider 120 and signal CK_NUM and configured to transmit signal CK_NUM to output 102 if N is equal to 1 and signal READY_NUM is at the second value and to transmit the output signal of frequency divider 120 otherwise. This implementation mode enables to save resources when a division of the frequency of signal CK_NUM is unnecessary.

Device 100 forms, for example, part of an electronic device, for example a cell phone, a computer, an electronic tablet, etc.

FIG. 1B shows, in the form of blocks, another example of an electronic device 100′ generating clock signal CK_SOC.

Certain elements of FIG. 1B are similar to elements of FIG. 1A. They are designated with the same references and will not be described again in detail.

A circuit 106′ of device 100′ comprises inputs coupled to the output 110 of circuit 104 and to the output 114 of circuit 104 and is configured to take as input the clock signal CK supplied by output 110 and the signal READY supplied by output 114. Circuit 106′ also comprises inputs 116 and 117, and is configured to receive, at input 116, division factor N and, at input 117, parameter k. Circuit 106′ is configured to generate clock signal CK_SOC. As compared with the circuit 106 of FIG. 1A, circuit 106′ comprises, instead of divider 120, two frequency dividers DIV_N 130 and DIV_k 132. Frequency divider DIV_N is configured to receive signal CK_NUM and division factor N and to transmit a signal CK_N corresponding to signal CK_NUM with a frequency divided by N. Frequency divider DIV_k is configured to receive signal CK_NUM and parameter k and to transmit a signal CK_k corresponding to signal CK_NUM with a frequency divided by k. Circuit 106′ also comprises a selection circuit 136, for example a multiplexer, configured to receive signals CK_N and CK_k as inputs and READY_NUM signal as a control signal and configured to generate the signal CK_SOC corresponding to signal CK_k when signal READY_NUM is at the first value and corresponding to signal CK_N when signal READY_NUM is at the second value.

FIG. 1C schematically shows in the form of blocks an example of a phase-locked loop 150. This circuit forms, for example, part of the circuit 104 of FIG. 1A or of FIG. 1B, and is configured to generate signal READY and clock signal CK based on clock signal CK_REF.

Phase-locked loop 150 for example comprises a phase comparator 152 (Φ, “PHASE COMPARATOR”), a charge pump 154 (“Charge Pump”), a loop filter 156 (“LOOP FILTER”), and a voltage-controlled oscillator 158 (VCO, “VOLTAGE CONTROLLED OSCILLATOR”).

Voltage-controlled oscillator 158 is configured to generate clock signal CK, which is also supplied to a frequency divider DIV2 of phase-locked loop 150 via a feedback loop 160. Frequency divider DIV2 is configured to generate a signal CK_DIV2 corresponding to the signal CK having a frequency divided by an integer, this integer being equal to FQ_TARGET divided by the frequency of signal CK_REF. The signal CK_DIV2 generated by frequency divider DIV2 is transmitted to phase comparator 152.

Phase comparator 152 also takes as an input signal CK_REF and is configured to compare the frequency of signal CK_DIV2 with the frequency of signal CK_REF. Phase comparator 152 is, for example, configured to generate one or a plurality of signals representative of the difference between the frequencies of signals CK_DIV2 and CK_REF and to supply them to charge pump 154 and to a processing circuit RDY. In the example of FIG. 1C, phase comparator 152 is configured to generate a first signal “up” indicating that the frequency of signal CK_DIV2 is lower than the frequency of signal CK_REF, and the voltage supplied to VCO 158 increases. Phase comparator 152 is also configured to generate a second signal “down” indicating that the frequency of signal CK_DIV2 is greater than the frequency of signal CK_REF, and the voltage supplied to VCO 158 decreases.

Charge pump 154 is, for example, configured to generate a voltage having its level depending on the comparison of signals CK_REF and CK_DIV2. For example, the output voltage of charge pump 154 increases if the frequency of signal CK_DIV2 is lower than the frequency of signal CK_REF.

Loop filter 156 is, for example, configured to filter the output signal of the charge pump and to transmit it to VCO 158. VCO 158 is configured to generate signal CK with a frequency depending on the voltage received at its input. For example, if the frequency of CK_DIV2 is lower than the frequency of CK_REF and the voltage at the output of charge pump 154 increases, the voltage transmitted by loop filter 156 to the VCO also increases, and the frequency of the signal CK generated by VCO 158 increases in turn. When signal CK is stable, its frequency is equal to FQ_TARGET and signal CK_DIV2 has a frequency equal to CK_REF.

The frequency of signal CK_REF, for example, is lower than frequency FQ_TARGET. VCO 158 generates signal CK at a frequency higher than CK_REF. The presence of frequency divider DIV2 allows a comparison of signal CK with signal CK_REF, via the generation of signal CK_DIV2.

Processing circuit RDY is configured to generate signal READY as a function of the signal(s) resulting from the comparison of signals CK_REF and CK_DIV2. For example, signal READY takes the second value when the phase-locked loop is locked, that is, when the frequency of signal CK_DIV2 is different from a maximum of x % of the frequency of signal CK_REF, for example over a plurality of successive control loops, where x is in the range from 1 to 10%, and preferably equal to approximately 5%.

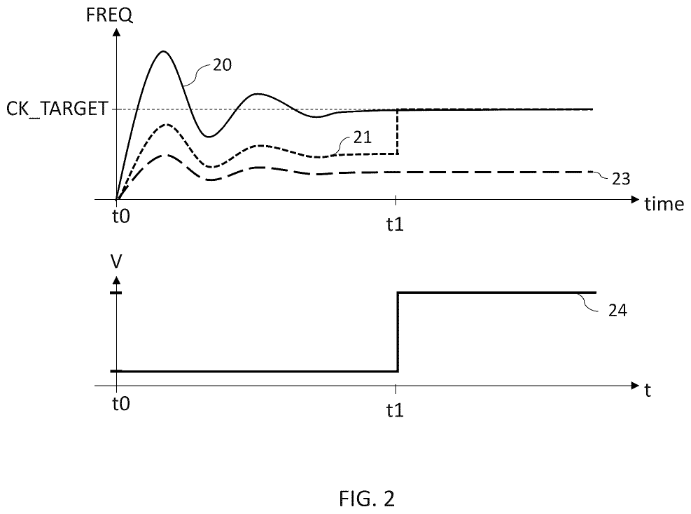

FIG. 2 graphically shows an example of the variation of the frequency (“FREQ”) 20 of clock signal CK over time (“t”), the variation of the frequency 21 of the corresponding output clock signal CK_SOC if the division factor N is equal to 1, the variation of the frequency 23 of the corresponding output clock signal CK_SOC if division factor N is equal to 3, and of the voltage (“V”) 24 of the signal READY_NUM generated by the device 100 of FIG. 1A or by the device 100′ of FIG. 1B.

According to an embodiment, signal CK is generated by circuit 104 from time to, for example when circuit 104 is switched on. During a period running from t0 to t1, the frequency 20 of signal CK significantly varies over time and, for example, takes values higher than frequency FQ_TARGET, and the voltage 24 of signal READY_NUM is at the first value, for example a low voltage.

At time t1, the frequency 20 of signal CK has reached frequency FQ_TARGET and is stable. At time t1, the voltage 24 of signal READY_NUM switches from the first value to the second value, for example, signal READY_NUM switches from a low voltage to a high voltage. After time t1, signal READY_NUM remains at the second value.

If division factor N is equal to 1, between time t0 and time t1, the frequency 21 of signal CK_SOC is equal to the frequency 20 of signal CK divided by parameter k, by 2 in the example of FIG. 2. The frequency 21 of signal CK_SOC is equal to the frequency 20 of signal CK from time t1. Parameter k is selected so that the frequency 21 of signal CK_SOC does not exceed frequency FQ_TARGET.

If division factor N is greater than k, for example 3, the frequency 21 of signal CK_SOC is for example equal to the frequency 20 of signal CK divided by division factor N. Despite the frequency variations present between time t0 and time t1, frequency 23 for example does not exceed frequency FQ_TARGET.

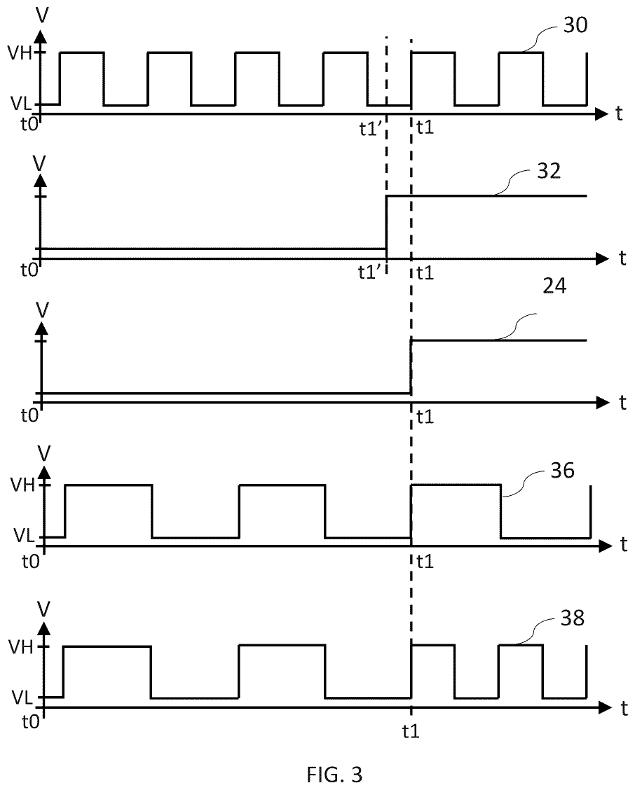

FIG. 3 is a timing diagram showing an example of the signals present in the device of FIG. 1B. There are shown the variation of the voltage (“V”) 30 of digital clock signal CK_NUM and of the voltage 32 of the signal READY transmitted by circuit 104 over time (“t”), the variation of the voltage 24 of signal READY_NUM, the variation of the voltage 36 of signal CK_k, and the variation of the voltage 38 of signal CK_SOC.

Signal CK_NUM is a signal oscillating between two values, for example a low voltage (“VL”) and a high voltage (“VH”), over time. Its frequency varies, for example, between time t0 of FIG. 2, corresponding, for example, to the starting of circuit 104, and a time t1′, corresponding to the time when signal CK is considered as stable by circuit 104, and thus corresponding to the time of the switching of signal READY between the first value and the second value. In the example of FIG. 3, the voltage 30 of signal CK_NUM is a square-wave signal comprising rising edges, corresponding to times when the signal switches from the low voltage to the high voltage, and falling edges, corresponding to times when the signal switches from the high voltage to the low voltage. A time t1 corresponds, for example, to the edge of signal CK_NUM following time t1′. According to the embodiment illustrated in FIG. 3, time t1 corresponds to the rising edge of signal CK_NUM following time t1′. According to another embodiment, not illustrated, time t1 corresponds to the falling edge of signal CK_NUM following time t1′.

According to an embodiment, signal CK is generated by circuit 104 from time t0. During a period running from time t0 to time t1′, the frequency of signal CK varies, for example, over time and takes values higher than the target frequency such as defined by frequency FQ_TARGET, and the voltage 32 of signal READY is at the first value, for example a low voltage.

At time t1′, the frequency of signal CK has reached target value FQ_TARGET and is stable. At time t1′, the voltage 32 of signal READY switches from the first value to the second value, for example, signal READY switches from a low voltage to a high voltage. After time t1′, signal READY remains at the second value. Time t1 being after time t1′, signal READY is at the second voltage value.

Signal READY_NUM takes a third voltage value between times t0 and t1 and a fourth voltage value after time t1. The third voltage value is, for example, lower than the fourth voltage value. According to an embodiment, the third voltage value is equal to the first voltage value and the fourth voltage value is lower than the second voltage value. The transition from the third voltage value to the fourth voltage value is performed at time t1, defined hereabove.

In the example of FIG. 3, parameter k is equal to 2 and signal CK_SOC is obtained for a division factor N equal to 1. The frequency of signal CK_k corresponds to the frequency of signal CK_NUM divided by parameter k, that is, 2. In the example of FIG. 3, signal CK_k is a square-wave signal oscillating between values VL and VH.

Between times t0 and t1, signal CK_SOC corresponds to signal CK_k, and from time t1, signal CK_SOC corresponds to signal CK_N, not illustrated in FIG. 3, equal to signal CK_NUM in the case where N is equal to one.

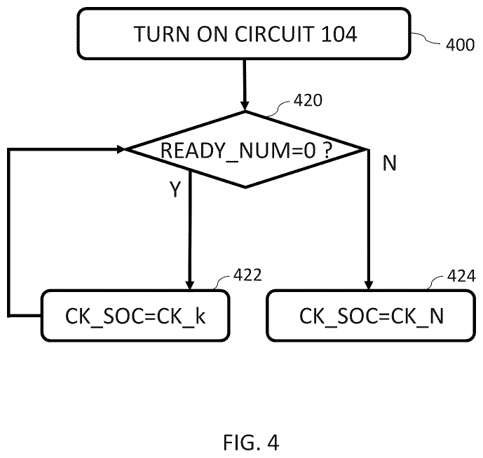

FIG. 4 shows, in the form of a flowchart, a method of generation of the clock signal CK_SOC of FIGS. 1A to 3.

At a step 400 (“TURN ON CIRCUIT 104”), circuit 104 is switched on. Signals CK and READY are generated by circuit 104 and, for example, synchronized by circuit 106.

At a step 420 (“READY_SYNC−0?”) following step 400, signal READY_NUM is read by the control circuit 126 of FIG. 1A or by the control circuit 136 of FIG. 1B and the value of signal READY_NUM is compared with the first value, for example.

If, at step 420, signal READY_NUM is at the first value (output “Y” of block 420), then, at a step 422 (“CK_SOC=CK_k”), control circuit 126 is configured to transmit parameter k to frequency divider 120 or selection circuit 136 is configured to transmit the output clock signal CK_SOC corresponding to signal CK_k. After step 422, the method returns to step 420, which is repeated until signal READY_NUM takes the second value.

If, at step 420, signal READY_NUM is at the second value (output “N” of block 420), then, at a step 424 (“CK_SOC=CK_N”), control circuit 126 is configured to transmit division factor N to frequency divider 120 or selection circuit 136 is configured to transmit the output clock signal CK_SOC corresponding to signal CK_N.

An advantage of dividing the frequency of signal CK_NUM by k between times t0 and t1, if division factor N is smaller than parameter k, is that the system on chip clocked by clock signal CK_SOC may use signal CK_SOC from time t0, decreasing the risk for the frequency of signal CK_SOC to be too high.

Various embodiments and variants have been described. Those skilled in the art will understand that certain features of these various embodiments and variants may be combined, and other variants will occur to those skilled in the art. In particular, although the case of being able to vary the division factor N is provided, in other cases, it is always desired to use a signal with the frequency of signal CK undivided and the division factor N is not supplied to device 100.

Finally, the practical implementation of the described embodiments and variants is within the abilities of those skilled in the art based on the functional indications given hereabove. For example, frequency dividers are well known in the art and their practical implementation is thus within the abilities of those skilled in the art.

1. An electronic device, comprising:
a first electronic circuit configured to generate a first clock signal and a second signal indicating a state of stability of a frequency of the first clock signal, the second signal having a first value during a first period from a starting of the first electronic circuit and a second value after the first period; and
a second electronic circuit configured to generate an output clock signal having a frequency equal to the frequency of the first clock signal divided by a first factor when the second signal is at the first value and having the frequency of the first clock signal, or a frequency equal to the frequency of the first clock signal divided by a second factor smaller than the first factor, as a consequence of a change of the second signal to the second value.

2. The electronic device of claim 1, wherein the second electronic circuit is configured to generate the output clock signal having a frequency equal to the frequency of the first signal divided by the second factor, from the time of the edge of the first clock signal following the change of the second signal to the second value.

3. The electronic device according to claim 1, wherein the first electronic circuit comprises a phase-locked loop configured to generate the first clock signal and the second signal.

4. The electronic device according to claim 1, wherein the second electronic circuit comprises a frequency divider configured to perform the division of the frequency of the first clock signal.

5. The electronic device according to claim 4, wherein the second electronic circuit comprises a multiplexer having an output coupled to a divider control input of the frequency divider, a first input configured to receive the first factor and a second input configured to receive the second factor, the multiplexer being configured to transmit the first factor when the second signal is at the first value and to transmit the second factor when the second signal is at the second value.

6. The electronic device according to claim 1, wherein the second electronic circuit comprises:
a first frequency divider having a divider control input configured to receive the first factor and configured to perform the division of the frequency of the first clock signal by the first factor; and
a second frequency divider having a divider control input configured to receive the second factor and configured to perform the division of the frequency of the first clock signal by the second factor.

7. The electronic device according to claim 6, wherein the second electronic circuit comprises a multiplexer having a first input coupled to an output of the first frequency divider and a second input coupled to an output of the second frequency divider, wherein the multiplexer is configured to transmit a signal received at the first input when the second signal is at the first value and to transmit a signal received on the second input when the second signal is at the second value.

8. The electronic device according to claim 1, wherein the second circuit comprises a synchronization circuit configured to synchronize the second signal with the first clock signal.

9. The electronic device according to claim 1, wherein the first factor is an integer greater than or equal to two.

10. A method of generating an output clock signal, comprising:
generating, by a first electronic circuit, a first clock signal and a second signal indicating a state of stability of a frequency of the first clock signal, the second signal having a first value during a first period from a starting of the first electronic circuit and a second value after the first period; and
generating, by a second electronic circuit, the output clock signal having a frequency equal to the frequency of the first clock signal divided by a first factor when the second signal is at the first value and having the frequency of the first clock signal, or a frequency equal to the frequency of the first clock signal divided by a second factor smaller than the first factor, as a consequence of a change of the second signal to the second value.

11. The method of claim 10, wherein the output clock signal has a frequency equal to the frequency of the first signal divided by the second factor, from the time of the edge of the first clock signal following the change from the second signal to the second value.

12. The method according to claim 10, further comprising synchronizing the second signal with the first signal using a synchronization circuit.

13. The method according to claim 10, wherein the first factor is an integer greater than or equal to two.

14. The method according to claim 10, further comprising, after generating the first clock signal and the second signal, converting the first clock signal and the second signals from analog signals into digital signals.

15. The method according to claim 10, further comprising transmitting, by the second electronic circuit, via a multiplexer to a frequency divider, the first factor to control division by the frequency divider when the second signal is at the first value and the second factor to control division by the frequency divider when the second signal is at the second value.

16. The method according to claim 10, further dividing the frequency of the first clock signal by the first factor by a first frequency divider of the second electronic circuit and dividing the frequency of the first clock signal by the second factor by a second frequency divider of the second electronic circuit.

17. The method according to claim 16, further comprising transmitting, by a multiplexer of the second electronic circuit, a signal output from the first frequency divider when the second signal is at the first value and a signal output from the second frequency divider when the second signal is at the second value.
